(19) United States
(12) Patent Application Publication
(10) Pub. No.: US 2006/0258191 A1
(43) Pub. Date: Nov. 16, 2006

(54) Contact terminal structure

(76) Inventor: Wan-Tien Chen, Taipei (TW)

Correspondence Address: LOWE HAUPTMAN BERNER, LLP, 1700 DIAGONAL ROAD, SUITE 300, ALEXANDRIA, VA, 22314, US

(21) Appl. No.: 11/127,229

(22) Filed: May 12, 2005

(51) Int. Cl. H05K 1/00

(52) U.S. Cl. 439/83

(57) ABSTRACT

A contact terminal structure to be disposed into the terminal block on the base of an integrated circuit, comprises a main body, a soldering end extending from one end of said main body and being used for placing a solder ball, and a contact end extending from another end of said main body and provided contortedly with a corresponding contact portion at an appropriate position thereon. This structure can allow a solder ball be more easily and precisely bonded with said soldering portion by two rounded opposite holding faces each provided with a zigzag protruding portion.

### BACKGROUND OF THE INVENTION

1. Field of the Invention

The invention relates to a contact terminal structure, more particularly to a structure for solving the problem of the bonding and alignment between a solder ball and a contact terminal such that the solder ball can be more easily and precisely bonded with the contact terminal.

2. Description of the Prior Art

It is known, in the past, the contact bonding between a base and a motherboard in an integrated circuit was in a manner of mounting before soldering. But at present, the contact bonding is gradually adopting a manner of placing a solder ball on a contact terminal in an integrated circuit base first, and then soldering the integrated circuit base on a motherboard directly by means of a soldering process.

Currently, a contact terminal commercially available is in a form that is provided with a long hole and bended into a clamp-like shape, wherein said long hole on the contact terminal is used for mounting a pin on the integrated circuit board, and wherein its solder ball is placed on the open end of the contact terminal.

However, there are several disadvantages associated with this kind of contact terminal because the bonding between the contact terminal and the solder ball is relatively uneasy to be done and a fluctuation tends to be caused between adjacent solder balls and the solder ball tends to drop off during its placing. Furthermore, no aligning structure exists between the contact terminal and the base such that after mounting the contact terminal into the terminal block on the base, a fluctuation could be caused. Consequently, in view of the foregoing, it is evident that this prior art structure could not result in a correct contact between the base and the motherboard of an integrated circuit.

Further, a structure as disclosed in U.S. Pat. No. 6,267,615 comprising a contact terminal consisted essentially of a base part, a wing part, a flexible arm, a holding part and a supporting part, wherein said wing part was provided contortedly on appropriate positions over both sides of the base part, wherein ends of two wing parts were extended upwardly and separately resulting into a tapered flexible arm, and wherein said holding part had an asymmetric guiding face.

In the structure as disclosed in U.S. Pat. No. 6,267,615, the supporting part of said contact terminal was a plane without any alignment structure, and therefore, the solder ball could not be aligned precisely during placing. Consequently, this structure could not give a correct electrical contact between the base and the motherboard of an integrated circuit, too.

### SUMMARY OF THE INVENTION

A main objective of the invention is to solve and/or avoid above-described disadvantages associated with the prior art, and make possible bonding more easily and precisely for the solder ball with the soldering portion on the contact terminal.

For achieving the above-mentioned objective, the invention provides a contact terminal structure consisted of a main body, a soldering end and a contact end, wherein said soldering end has an aligning portion of an arcuate hollow shape, and a holding face of a rounded concave form is provided over both opposite sides of said aligning portion, thereby a soldering ball can be held securely by said holding face of said aligning portion of said soldering end.

These features, effects, advantages and technical content of the contact terminal according to the present invention will be fully understood and appreciated from the following detailed description of the accompanying drawings.

### BRIEF DESCRIPTION OF THE DRAWINGS

FIG. 1 is a perspective schematic view of an embodiment of a contact terminal according to the invention;

FIG. 2 is a schematic view showing the practice of an embodiment of the contact terminal according to the invention; and

FIG. 3 is a perspective schematic view of another embodiment of a contact terminal according to the invention.

### DETAILED DESCRIPTION OF THE PREFERRED EMBODIMENT

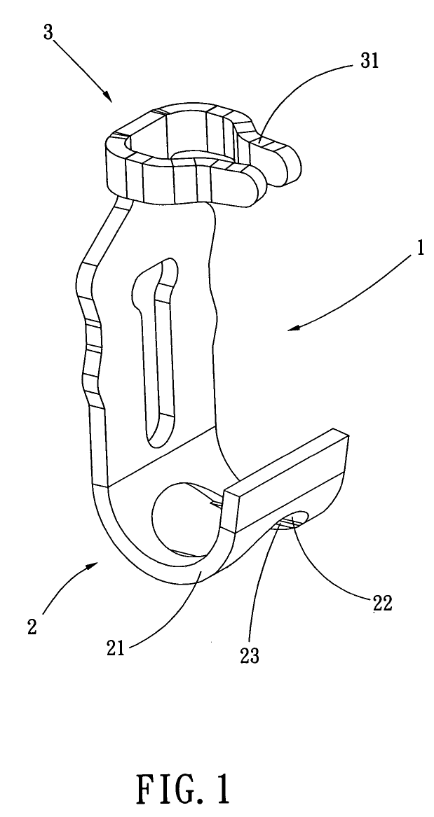

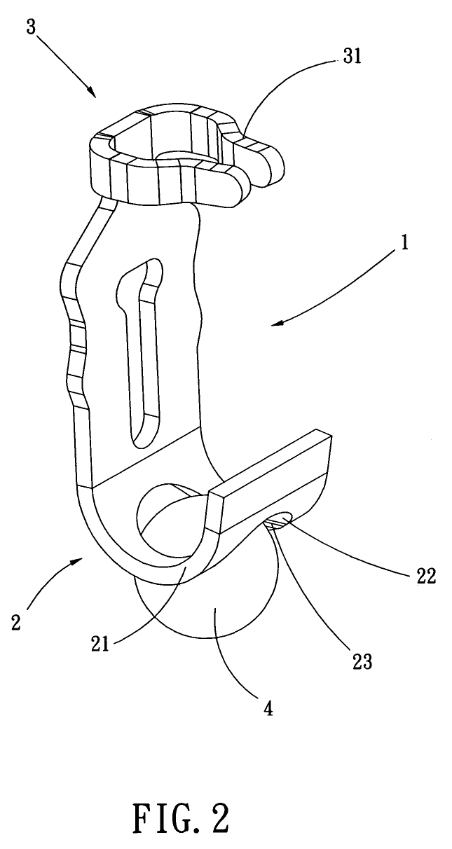

Referring to FIGS. 1 and 2, showing schematically the perspective view and the practice of an embodiment of a contact terminal structure according to the invention, respectively, said contact terminal structure comprises:

a main body 1; and

a soldering end 2, extending from one end of said main body 1 and being used for placing a solder ball 4, wherein said soldering end 2 has an aligning portion 21 of an arcuate hollow shape, and a holding face 22 of a rounded concave form is provided over both opposite sides of said aligning portion 21, thereby a soldering ball 4 can be held securely by said rounded opposite holding faces 22 each provided with a zigzag protruding portion 23; and

a contact end 3, extending from another end of said main body 1 and provided contortedly with a corresponding contact portion 31 at an appropriate position thereon;

thereby, said solder ball 4 can be more easily and precisely bonding with said contact terminal by means of said rounded opposite concave holding faces 22 and said zigzag protruding portion 23.

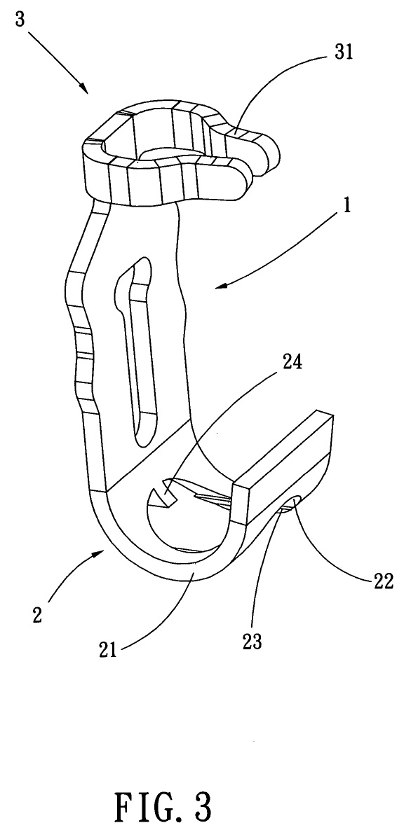

Referring to FIG. 3, a schematic view of another embodiment of a contact terminal according to the invention is shown, wherein, in order to assure that said solder ball 4 can be aligned more precisely on the contact terminal, a strengthening pole 24 is provided by extending from an appropriate position immediately adjacent to said two rounded opposite holding faces 22, thereby a 3-way contact plane can be formed so as to hold said solder ball 4 more securely.

As described above, by means of the contact terminal according to the invention, a solder ball can place more easily and precisely onto a pre-determined position, and consequently, said solder ball can be bonded intimately with said contact terminal during reflowing.

As understood from the foregoing, the contact terminal structure according to the invention can eliminate effectively various disadvantages associated with the prior art structure, and give improvements as well as more usefulness, thereby meets the requirement of patentability. While the foregoing has described preferred embodiments according to the invention, the scope of the invention is understood to be not limited thereto. Further, all of equivalent changes and modifications that can be made without departing from the scope of the invention are intended to fall within the scope of the invention as defined in the appended claims.

1. A contact terminal structure to be disposed into the terminal block on the base of an integrated circuit, the structure comprising:
a main body;
a soldering end, extending from one end of said main body having an aligning portion of an arcuate hollow shape, wherein the aligning portion includes a first holding face of a rounded concave form and a second holding face of a rounded concave form provided on opposite sides of said aligning portion; and
a contact end, extending from another end of said main body including a corresponding, contorted contact portion.

2. A contact terminal structure to be disposed into the terminal block on the base of an integrated circuit, the structure comprising:
a main body;
a soldering end, extending from one end of said main body having an aligning portion of an arcuate hollow shape, wherein the aligning portion includes a first holding face of a rounded concave form and a second holding face of a rounded concave form provided on opposite sides of said aligning portion; and
a contact end, extending from another end of said main body including a corresponding, contorted contact portion, wherein, said first and second holding faces are each provided with a zigzag protruding portion configured to securely hold a solder ball.

3. A contact terminal structure of claim 1, further comprising a strengthening pole extending from the aligning portion at a position where said first and second holding faces meet configured to provide in conjunction with the first and second holding faces a 3-way contact plane to securely hold a solder ball.

4. A contact terminal structure to be disposed into the terminal block on the base of an integrated circuit, the structure comprising:
a main body;
a soldering end, extending from one end of said main body having an aligning portion including two halves that are mirrored and opposite to each other and a cutout forming a hollow, three-dimensional saddle shape framed by the opposite halves, wherein the aligning portion includes a first holding face of a rounded concave form and a second holding face of a rounded concave form provided on opposite sides of said aligning portion, said first and second holding faces forming the hollow, three dimensional saddle shape; and
a contact end, extending from another end of said main body including a corresponding, contorted contact portion.

5. A contact terminal structure of claim 4 wherein, said first and second holding faces are each provided with a zigzag protruding portion configured to securely hold a solder ball.

6. A contact terminal structure of claim 4, further comprising a strengthening pole extending from the aligning portion between said first and second halves configured to provide in conjunction with the first and second holding faces a 3-way contact plane to securely hold a solder ball.
